(19) United States
(12) Patent Application Publication
(10) Pub. No.: US 2024/0160104 A1
(43) Pub. Date: May 16, 2024

(54) PHOTOSENSITIVE COMPOSITION, AND CURED FILM

(71) Applicants: National University Corporation Kyoto Institute of Technology, Kyoto (JP); JNC CORPORATION, Tokyo (JP)

(72) Inventors: NAOKI WATANABE, Chiba (JP); KENSUKE NAKA, Kyoto (JP); KIMIHIRO MATSUKAWA, Kyoto (JP); HIROAKI IMOTO, Kyoto (JP)

(73) Assignees: National University Corporation Kyoto Institute of Technology, Kyoto (JP); JNC CORPORATION, Tokyo (JP)

(21) Appl. No.: 18/348,374

(22) Filed: Jul. 7, 2023

(30) Foreign Application Priority Data
Oct. 31, 2022 (JP) 2022-174462

(51) Int. Cl. G03F 7/075

(52) U.S. Cl. CPC G03F 7/0755

(57) ABSTRACT

A photosensitive composition can give a cured film exhibiting high heat resistance and self-repairing properties by light irradiation and low-temperature heating. The photosensitive composition contains a double-decker silsesquioxane (A) having two or more polymerizable double bonds, and a polythiol (B).

### CROSS-REFERENCE TO RELATED APPLICATION

This application claims priority benefits of Japanese Patent Application No. 2022-174462, filed on Oct. 31, 2022. The entirety of the above-mentioned patent application is hereby incorporated by reference herein and made a part of this specification.

### BACKGROUND

### Technical Field

The disclosure relates to a photosensitive composition and a cured film.

### Description of Related Art

Resin materials are used in various applications such as electronic materials and automotive materials because of their excellent mechanical properties and thermal properties. In recent years, each product has been required to have higher performance and higher added value, and resin materials are also required to have higher performance and higher functionality.

As an example of performance improvement, high heat resistance is imparted, and examples using silsesquioxane have been reported so far. Patent Document 1 proposes a photosensitive composition that provides a cured product that has high heat resistance and transparency and is capable of evenly and stably color-converting light emitted from an optical semiconductor over a long period of time.

In addition, examples of high functionality include imparting self-repairing properties such that scratches on the surface of the cured film can be repaired by themselves or can be repaired by performing a simple treatment. Non-Patent Document 1 reports an example of a self-repairing material containing polyrotaxane as a main component.

### PATENT DOCUMENTS

[Patent Document 1] WO 2012/111765 A1

### NON-PATENT DOCUMENTS

[Non-Patent Document 1] Japan Science and Technology Agency, “Development of a coating material that can self-repair dents and cuts—potential for commercialization in a wide range of fields from car coatings to hemostatic sheets—”, [online], 2016/11/11, [retrieved on 2022/09/29], Internet <URL: https://www.jst.go.jp/pr/announce/20161111/index.html>.

### SUMMARY

As described above, resin materials exhibiting one or two of properties such as photocurability or low-temperature curability, heat resistance, and self-repairing properties have been reported respectively. However, in order to further increase the added value of products, it is required to possess these three characteristics in combination. In recent years, in particular, not only performance and function after molding but also energy saving in the manufacturing process have been attracting attention. Therefore, the curable composition is also required to be cured with light or cured at a temperature lower than approximately 230° C., which is a general curing temperature, when manufacturing a cured product by curing.

Accordingly, it is required to provide a photosensitive composition that can give a cured film exhibiting high heat resistance and self-repairing properties by light irradiation and low-temperature heating.

The inventors have made intensive studies to solve the above problems, finding that a composition containing a double-decker silsesquioxane having two or more polymerizable double bonds and a polythiol is cured by light irradiation and low-temperature heating, and a cured film exhibiting high heat resistance and self-repairing properties can be obtained, thus completing the disclosure.

The disclosure includes the following configurations.
[1] A photosensitive composition containing: a double-decker silsesquioxane (A) having two or more polymerizable double bonds, and a polythiol (B).
[2] The photosensitive composition of [1] in which the double-decker silsesquioxane (A) having two or more polymerizable double bonds is a silsesquioxane represented by formula (1) below.

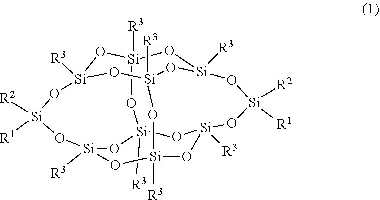

In formula (1), R¹ is a substituted or unsubstituted hydrocarbon group of 2 to 20 carbons having a polymerizable double bond, or a group represented by R⁴(R⁵)₂SiO—, R⁴ is a substituted or unsubstituted hydrocarbon group of 2 to 20 carbons having a polymerizable double bond, R⁵'s are each independently a substituted or unsubstituted hydrocarbon group of 1 to 20 carbons, R²'s and R³'s are each independently a substituted or unsubstituted hydrocarbon group of 1 to 20 carbons, a plurality of R¹'s may be the same as or different from each other, a plurality of R²'s may be the same as or different from each other, a plurality of R³'s may be the same as or different from each other, when there is a plurality of R⁴'s, the plurality of R⁴'s may be the same as or different from each other, and when there is a plurality of R⁵'s, the plurality of R⁵'s may be the same as or different from each other.)
[3] The photosensitive composition of [1] or [2] in which the double-decker silsesquioxane (A) having two or more polymerizable double bonds is a silsesquioxane represented by formula (Ia) below.

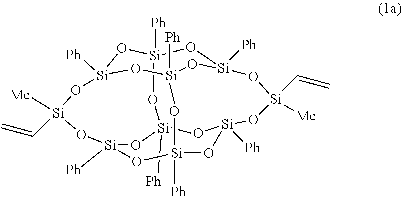 [SMILES: C=C[Si]1(C)O[Si]2(c3ccccc3)O[Si]3(c4ccccc4)O[Si]4(c5ccccc5)O[Si](C)(C=C)O[Si]5(c6ccccc6)O[Si](c6ccccc6)(O[Si](c6ccccc6)(O1)O[Si](c1ccccc1)(O5)O[Si](c1ccccc1)(O2)O4)O3]

[4] The photosensitive composition of any one of [1] to [3] in which the content of the polythiol (B) is 5 parts by mass or more and 40 parts by mass or less with respect to 100 parts by mass of the double-decker silsesquioxane (A).
[5] The photosensitive composition of any one of [1] to [4] which further contains an organic solvent (C).
[6] A cured film obtained by curing the photosensitive composition of any one of [1] to [5].

According to the disclosure, it is possible to provide a photosensitive composition that can give a cured film exhibiting high heat resistance and self-repairing properties by light irradiation and low-temperature heating.

### DESCRIPTION OF THE EMBODIMENTS

### 1. Photosensitive Composition

A photosensitive composition according to one embodiment of the disclosure contains: a double-decker silsesquioxane (A) having two or more polymerizable double bonds and a polythiol (B). When the photosensitive composition according to the present embodiment contains these components, the thiol-ene reaction can proceed under mild conditions such as light irradiation and low-temperature heating, and oligomerization or polymerization proceeds. Moreover, by using a double-decker silsesquioxane having two or more polymerizable double bonds, various properties such as high heat resistance and self-repairing properties can be imparted to the cured film.

In this specification, a polymerizable double bond means a carbon-carbon double bond. Further, in this specification, giving a cured film by light irradiation and low-temperature heating means that a cured film is formed, in addition to light irradiation, by heating with a temperature lower than about 230° C., which is a conventional general curing temperature (for example, 200° C., 180° C., 150° C., 120° C., or 100° C.), and polymerizing the polymerizable compound in the composition.

### 1-1. Double-decker silsesquioxane (A)

The double-decker silsesquioxane (A) having two or more polymerizable double bonds (hereinafter sometimes referred to as “double-decker silsesquioxane (A)”, “component (A)”, and the like) is not particularly limited as long as the double-decker silsesquioxane is a compound in which two or more functional groups having a polymerizable double bond are substituted on the double-decker silsesquioxane skeleton. The number of the polymerizable double bonds of the double-decker silsesquioxane (A) is preferably 2 or more and 6 or less, more preferably 2 or more and 4 or less, and still more preferably 2. Preferred examples of the double-decker silsesquioxane (A) include compounds represented by formula (1) below. The double-decker silsesquioxane (A) may be used singly, or two or more thereof may be used in any combination and ratio.

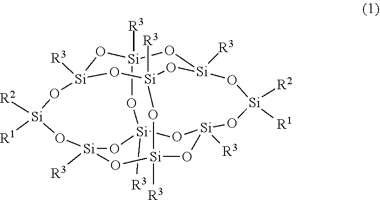

In formula (1), R¹ is a substituted or unsubstituted hydrocarbon group of 2 to 20 carbons having a polymerizable double bond, or a group represented by R⁴(R⁵)2SiO—. The two R¹'s in formula (1) may be the same or different from each other.

In addition, in this specification, the scope of a hydrocarbon group includes an aliphatic hydrocarbon group and an aromatic hydrocarbon group. The aliphatic hydrocarbon group is not limited to a linear one, and may have a branched structure or a cyclic structure. In addition, the aromatic hydrocarbon group may be monocyclic, polycyclic, or condensed cyclic, or may be a heterocyclic aromatic hydrocarbon group.

Further, in this specification, when the hydrocarbon group has a substituent, the number of carbon atoms in the hydrocarbon group includes the number of carbon atoms in the substituent.

The number of polymerizable double bonds in the substituted or unsubstituted hydrocarbon group of 2 to 20 carbons having a polymerizable double bond as represented by R¹ is not particularly limited, and is usually 1 or more, preferably 4 or less, and more preferably 2 or less.

When the hydrocarbon group is an aliphatic hydrocarbon group, the number of carbon atoms in the substituted or unsubstituted hydrocarbon group of 2 to 20 carbons having a polymerizable double bond as represented by R¹ is preferably 2 or more and 16 or less, 2 or more and 12 or less, and more preferably 2 or more and 8 or less. When the hydrocarbon group is an aromatic hydrocarbon group, the number of carbon atoms in the hydrocarbon group is usually 3 or more and 20 or less, preferably 6 or more and 20 or less, more preferably 6 or more and 16 or less, and still more preferably 6 or more and 12 or less.

Examples of unsubstituted aliphatic hydrocarbon groups of 2 to 20 carbons having a polymerizable double bond as represented by R¹ include: vinyl, allyl, 1-propenyl, isopropenyl, 1-butenyl, 2-butenyl, 3-butenyl, 2-methylallyl, 2-methyl-1-propenyl, 4-pentenyl, 5-hexenyl, 6-heptenyl, 7-octenyl, 8-nonenyl, 9-decenyl, 10-undecenyl, 11-dodecenyl, 12-tridecenyl, 13-tetradecenyl, 14-pentadecenyl, 15-hexadecenyl, 16-heptadecenyl, 17-octadecenyl, 18-nonadecenyl, and 19-icosenyl.

Examples of the aromatic hydrocarbon group of 2 to 20 carbons having a polymerizable double bond represented by R¹ include: a group in which an unsubstituted aromatic hydrocarbon group, such as phenyl, 1-naphthyl, 2-naphthyl, 1-phenanthryl, 2-phenanthryl, 3-phenanthryl, 4-phenanthryl, 9-phenanthryl, 1-anthryl, 2-anthryl, 9-anthryl, 1-pyrenyl, 2-pyrenyl, 4-pyrenyl, 1-triphenylenyl, 2-triphenylenyl, 2-triazinyl, 2-pyridyl, 3-pyridyl, 4-pyridyl, and 2-pyrazinyl, is substituted with an alkenyl group of 2 to 6 carbons, which will be described later.

When the hydrocarbon group of 2 to 20 carbons having a polymerizable double bond as represented by R¹ has a substituent, examples of the substituent include: a deuterium atom; alkyl of 1 to 6 carbons such as methyl, ethyl, n-propyl, isopropyl, n-butyl, sec-butyl, isobutyl, tert-butyl, n-pentyl, neopentyl, and n-hexyl; alkenyl of 2 to 6 carbons such as vinyl, allyl, 1-propenyl, isopropenyl, 1-butenyl, 2-butenyl, 3-butenyl, 2-methylallyl, 2-methyl-1-propenyl, 4-pentenyl, and 5-hexenyl; cycloalkyl of 3 to 6 carbons such as cyclopropyl, cyclobutyl, cyclopentyl, and cyclohexyl; aromatic hydrocarbon groups of 6 to 10 carbons such as phenyl, 1-naphthyl, and 2-naphthyl; halogeno such as fluoro, chloro, bromo, and iodo; alkoxy of 1 to 6 carbons having the above alkyl groups of 1 to 6 carbons; cycloalkoxy of 3 or more and 6 or less carbons having a cycloalkyl group of 3 to 6 carbons; and a group represented by RCOO— or ROCO— (R is the above-described alkyl groups of 1 to 6 carbons, cycloalkyl groups of 3 to 6 carbons, or an aromatic hydrocarbon group of 6 to 10 carbons).

When R¹ is a group represented by R⁴(R⁵)₂SiO—, R⁴ is a substituted or unsubstituted hydrocarbon group of 2 to 20 carbons having a polymerizable double bond, and R⁵'s are each independently a substituted or unsubstituted hydrocarbon group of 1 to 20 carbons. In formula (1), when there is a plurality of R⁴'s, the plurality of R⁴'s may be the same or different, and when there is a plurality of R⁵'s, the plurality of R⁵'s may be the same or different.

A substituted or unsubstituted hydrocarbon group of 2 to 20 carbons having a polymerizable double bond as represented by R⁴ is synonymous with a substituted or unsubstituted hydrocarbon group of 2 to 20 carbons having a polymerizable double bond as represented by R¹, and a preferred aspect is also the same.

When the hydrocarbon group is an aliphatic hydrocarbon group, the number of carbon atoms in the substituted or unsubstituted hydrocarbon group of 1 to 20 carbons represented by R⁵ is preferably 2 or more and 16 or less, 2 or more and 12 or less, and more preferably 2 or more and 8 or less. When the hydrocarbon group is an aromatic hydrocarbon group, the number of carbon atoms in the hydrocarbon group is usually 3 or more and 20 or less, preferably 6 or more and 20 or less, more preferably 6 or more and 16 or less, and still more preferably 6 or more and 12 or less.

Examples of unsubstituted aliphatic hydrocarbon groups of 1 to 20 carbons represented by R⁵ include: alkyls such as methyl, ethyl, n-propyl, isopropyl, n-butyl, sec-butyl, tert-butyl, isobutyl, n-pentyl, isopentyl, neopentyl, n-hexyl, n-heptyl, n-octyl, n-nonyl, n-decyl, n-undecyl, n-dodecyl, n-tridecyl, n-tetradecyl, n-pentadecyl, n-hexadecyl, n-heptadecyl, n-octadecyl, n-nonadecyl, and n-docosyl; cycloalkyls such as cyclopropyl, cyclobutyl, cyclopentyl, and cyclohexyl; and alkynyls such as propargyl. In addition to these, the unsubstituted hydrocarbon group of 1 to 20 carbons may be an unsubstituted aliphatic hydrocarbon group of 2 to 20 carbons having a polymerizable double bond as described above.

Examples of the unsubstituted aromatic hydrocarbon group of 3 to 20 carbons represented by R⁵ include: phenyl, 1-naphthyl, 2-naphthyl, 1-phenanthryl, 2-phenanthryl, 3-phenanthryl, 4-phenanthryl, 9-phenanthryl, 1-anthryl, 2-anthryl, 9-anthryl, 1-pyrenyl, 2-pyrenyl, 4-pyrenyl, 1-triphenylenyl, 2-triphenylenyl, 2-triazinyl, 2-pyridyl, 3-pyridyl, 4-pyridyl, and 2-pyrazinyl.

When the hydrocarbon group of 1 to 20 carbons represented by R⁵ has a substituent, examples of the substituent include those described as a substituent that a hydrocarbon group of 2 to 20 carbons having a polymerizable double bond as represented by R¹ may have.

Among those described above, R¹ is preferably an unsubstituted aliphatic hydrocarbon group of 2 to 20 carbons having a polymerizable double bond, more preferably vinyl or allyl, and still more preferably vinyl. In addition, two R¹'s in formula (1) are preferably the same.

In formula (1), R²'s and R³'s are each independently a substituted or unsubstituted hydrocarbon group of 1 to 20 carbons. The two R²'s in formula (1) may be the same or different. In addition, the eight R³'s in formula (1) may be the same or different.

The substituted or unsubstituted hydrocarbon group of 1 to 20 carbons represented by R² or R³ is synonymous with the substituted or unsubstituted hydrocarbon group of 1 to 20 carbons represented by R⁵.

Among those described above, R² is preferably an unsubstituted aliphatic hydrocarbon group of 1 to 20 carbons, preferably methyl, ethyl, n-propyl, isopropyl, n-butyl, sec-butyl, tert-butyl, or isobutyl, more preferably methyl or ethyl, and still more preferably methyl. In addition, the two R²'s in formula (1) are preferably the same.

Among those described above, R³ is preferably an unsubstituted aromatic hydrocarbon group of 3 to 20 carbons, and more preferably phenyl. In addition, the eight R³'s in formula (1) are preferably the same.

Examples of a particularly preferable double-decker silsesquioxane (A) include a compound represented by the following formula (Ia), namely a compound of formula (1) in which R¹ is vinyl, R² is methyl and R³ is phenyl.

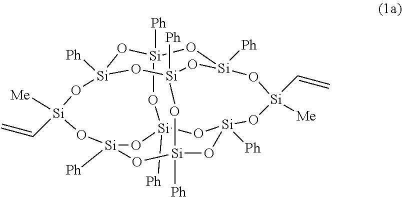 [SMILES: C=C[Si]1(C)O[Si]2(c3ccccc3)O[Si]3(c4ccccc4)O[Si]4(c5ccccc5)O[Si](C)(C=C)O[Si]5(c6ccccc6)O[Si](c6ccccc6)(O[Si](c6ccccc6)(O1)O[Si](c1ccccc1)(O5)O[Si](c1ccccc1)(O2)O4)O3]

The double-decker silsesquioxane (A) can be made by a known method or a method based on a known method. Examples of known methods include the method described in Japanese Patent Laid-Open No. 2006-022207. A commercially available compound may also be used as the double-decker silsesquioxane (A).

### 1-2. Polythiol (B)

Polythiol (B) (hereinafter sometimes referred to as “component (B)”) is not particularly limited as long as the polythiol (B) is a compound having two or more thiol groups (mercapto groups) per molecule. The number of thiol groups (mercapto groups) possessed by the polythiol (B) is usually 2 or more and 10 or less, preferably 2 or more and 6 or less, and more preferably 2 or more and 4 or less. The polythiol (B) may be used singly, or two or more thereof may be used in any combination and ratio.

Examples of the polythiol (B) include: esters of a polyol (such as ethylene glycol, tetramethylene glycol, trimethylolpropane, pentaerythritol, dipentaerythritol, polymethylene glycol, polyethylene glycol, and polypropylene glycol) and a thiol (mercapto) group-containing carboxylic acid (such as mercaptoacetic acid and 3-mercaptopropionic acid); mercaptoalkyl ethers of the polyols; and polymercaptoalkane, etc.

Specific examples of the polythiol (B) include: trimethylolpropane tris(thioglycolate), pentaerythritol tetrakis(thioglycolate), ethylene glycol bis(thioglycolate), tetraethylene glycol bis(3-mercaptopropionate), trimethylolpropane tris(3-mercaptopropionate), pentaerythritol tetrakis (3-mercaptothiopropionate), dipentaerythritol poly(3-mercaptopropionate), trimethylolpropane tris(3-mercaptopropyl) ether, pentaerythritol tetrakis(3-mercaptopropyl) ether, ethylene glycol bis(2-mercaptoethyl) ether, tetraethylene glycol bis(2-mercaptoethyl) ether, 1,4-butanedithiol, 1,6-hexanedithiol, and 1,10-decanedithiol, etc.

In the photosensitive composition according to the present embodiment, the content of the polythiol (B) is not particularly limited, but, from the viewpoint of the photocurability and the low-temperature curability, is preferably 5 parts by mass or more and 60 parts by mass or less, and more preferably 5 parts by mass or more and 40 parts by mass or less, with respect to 100 parts by mass of the double-decker silsesquioxane (A).

### 1-3. Organic Solvent (C)

The photosensitive composition according to the present embodiment may further contain an organic solvent (C) (hereinafter sometimes referred to as “component (C)”). As the organic solvent (C), those capable of dissolving the double-decker silsesquioxane (A) and the polythiol (B) are preferred. Examples of the organic solvent (C) include: hydrocarbon solvents (e.g., hexane, benzene, and toluene, etc.), ether solvents (e.g., diethyl ether, tetrahydrofuran (THF), 2-methyltetrahydrofuran, diphenyl ether, anisole, dimethoxybenzene, and cyclopentyl methyl ether (CPME), etc.), halogenated hydrocarbon solvents (e.g., methylene chloride, chloroform, and chlorobenzene, etc.), ketone solvents (e.g., acetone, methyl ethyl ketone, and methyl isobutyl ketone, etc.), alcohol solvents (e.g., methanol, ethanol, propanol, isopropanol, n-butyl alcohol, and tert-butyl alcohol, etc.), nitrile solvents (e.g., acetonitrile, propionitrile, and benzonitrile, etc.), ester solvents (e.g., ethyl acetate and butyl acetate, etc.), carbonate solvents (e.g., ethylene carbonate and propylene carbonate, etc.), amide solvents (e.g., N,N-dimethylformamide, N,N-dimethylacetamide, and N-methylpyrrolidone, etc.), hydrochlorofluorocarbons solvents (e.g., HCFC-141b and HCFC-225, etc.), hydrofluorocarbon (HFCs) solvents (e.g., HFCs of 2 to 6 carbons, etc.), perfluorocarbon solvents (e.g., perfluoropentane and perfluorohexane, etc.), alicyclic hydrofluorocarbon solvents (e.g., fluorocyclopentane and fluorocyclobutane, etc.), oxygen-containing fluorine solvents (e.g., fluoroether, fluoropolyether, fluoroketone, and fluoroalcohol, etc.), and aromatic fluorinated solvents (e.g., α,α,α-trifluorotoluene and hexafluorobenzene, etc.). The organic solvent (C) may be used singly, or two or more thereof may be used in any combination and ratio. When the photosensitive composition according to the present embodiment contains the organic solvent (C), the content of the organic solvent (C) is usually more than 0 mass % and 95 mass % or less, preferably 50 mass % or more and 95 mass % by or less, more preferably 70 mass % or more and 95 mass % or less, and still more preferably 80 mass % or more and 90 mass % or less, with respect to the total amount of the photosensitive composition. 1-4. Other components

The photosensitive composition according to the present embodiment may contain various additives in order to improve coating uniformity and adhesion between the cured film and the base material when forming a cured film by coating and curing the base material. Examples of the additives mainly include: compounds having a polymerizable double bond other than the double-decker silsesquioxane (A); surfactants (leveling agents); adhesion improvers such as silane coupling agents; antioxidants; molecular weight modifiers; ultraviolet absorbers; anti-aggregation agents; and water, etc.

1-4-1. Compound Having Polymerizable Double Bond Other than Double-Decker Silsesquioxane (A)

The photosensitive composition according to the present embodiment may include a compound having a polymerizable double bond other than the double-decker silsesquioxane (A) (hereinafter referred to as “another compound having a polymerizable double bond”). Other compounds having a polymerizable double bond may be used singly, or two or more thereof may be used in any combination and ratio.

The number of polymerizable double bonds possessed by other compounds having polymerizable double bonds is preferably 2 or more and 8 or less, more preferably 2 or more and 6 or less, and still more preferably 2 or more and 4 or less.

Examples of other compounds having polymerizable double bonds include: esters of a polyol (such as ethylene glycol, tetramethylene glycol, trimethylolpropane, pentaerythritol, dipentaerythritol, polymethylene glycol, polyethylene glycol, and polypropylene glycol, etc.) and a polymerizable double bond-containing carboxylic acid (such as acrylic acid and methacrylic acid, etc.); alkenyl ethers (such as vinyl ethers, allyl ethers, and butenyl ethers, etc.) of the polyols; polymerizable double bond-containing isocyanurates such as tri(acryloyloxyethyl) isocyanurate, tri(methacryloyloxyethyl) isocyanurate, and triallyl isocyanurate, etc.; alkenyl acrylates such as vinyl acrylate and allyl acrylate, etc.; alkenyl methacrylates such as vinyl methacrylate and allyl methacrylate, etc.; and vinyl aromatics such as divinylbenzene and trivinylbenzene, etc.

1-4-2. Surfactant

The photosensitive composition according to the present embodiment preferably contains a surfactant from the viewpoint of improving the wettability, leveling property, or coatability of the photosensitive composition to the base material. The surfactant may be used singly, or two or more thereof may be used in any combination and ratio.

Examples of commercially available products of the surfactant include Polyflow No. 45, Polyflow KL-245, Polyflow No. 75, Polyflow No. 90, and Polyflow No. 95 (all are trade names; produced by Kyoeisha Chemical Co., Ltd.); Disperbyk 161, Disperbyk 162, Disperbyk 163, Disperbyk 164, Disperbyk 166, Disperbyk 170, Disperbyk 180, Disperbyk 181, Disperbyk 182, BYK 300, BYK 306, BYK 310, BYK 320, BYK 330, BYK 342, BYK 346, BYK-UV 3500, and BYK-UV 3570 (all are trade names; produced by BYK-Chemie Japan K.K.); KP-341, KP-358, KP-368, KF-96-50CS, and KF-50-100CS (all are trade names; produced by Shin-Etsu Chemical Co., Ltd.); SURFLON SC-101 and SURFLON KH-40 (all are trade names; produced by AGC Seimi Chemical Co., Ltd.); FTERGENT 222F, FTERGENT 251, and FTX-218 (all are trade names; produced by NEOS Co., Ltd.); EFTOP EF-351, EFTOP EF-352, EFTOP EF-601, EFTOP EF-801, and EFTOP EF-802 (all are trade names; produced by Mitsubishi Materials Corporation); Megaface® F-410, Megaface® F-430, Megaface® F-444, Megaface® F-472SF, Megaface® F-475, Megaface® F-477, Megaface® F-552, Megaface® F-553, Megaface® F-554, Megaface® F-555, Megaface® F-556, Megaface® F-558, Megaface® F-563, Megaface® R-94, Megaface® RS-75, and Megaface® RS-72-K (all are trade names; produced by DIC Corporation); TEGO Rad 2200N and TEGO Rad 2250N (all are trade names; produced by Evonik Degussa Japan Co., Ltd.); and Silaplane® FM-0511 (trade name; produced by JNC Corporation).

When the photosensitive composition according to the present embodiment contains a surfactant, the content of the surfactant is preferably 0.01 mass % or more and 10 mass % or less with respect to the total amount of the photosensitive composition.

1-4-3. Coupling Agent

The photosensitive composition according to the present embodiment preferably contains a coupling agent from the viewpoint of improving the adhesion between the cured film formed from the photosensitive composition and the base material. The coupling agent may be used singly, or two or more thereof may be used in any combination and ratio.

Silane-based, aluminum-based and titanate-based compounds can be used as the coupling agent. Specific examples of the coupling agent include: silane coupling agents, such as vinyltrichlorosilane, vinyltrimethoxysilane, vinyltriethoxysilane, 2-(3,4-epoxycyclohexyl)ethyltrimethoxysilane, 3-glycidoxypropyldimethylethoxysilane, 3-glycidoxypropylmethyldiethoxysilane, 3-glycidoxypropyltriethoxysilane, 3-glycidoxypropyltrimethoxysilane, 3-aminopropyltrimethoxysilane, 3-aminopropyltriethoxysilane, 3-methacryloxypropyltrimethoxysilane, and 3-methacryloxypropyltriethoxysilane, etc.; aluminum-based coupling agents, such as acetoalkoxyaluminum diisopropylate, etc.; and titanate-based coupling agents, such as tetraisopropylbis(dioctylphosphite) titanate, etc. Among these, 3-glycidoxypropyltrimethoxysilane is preferred as being highly effective in improving adhesion. Commercially available coupling agents include Sila-Ace 5510 (produced by JNC Corporation) and Sila-Ace 5530 (produced by JNC Corporation).

When the photosensitive composition according to the present embodiment contains an adhesion improver, the content of the adhesion improver is preferably 0.01 mass % or more and 10 mass % or less with respect to the total amount of the photosensitive composition.

1-4-4. Antioxidant

The photosensitive composition according to the present embodiment preferably further contains an antioxidant from the viewpoint of improving the transparency of the cured film and from the viewpoint of preventing yellowing when the cured film is exposed to high temperatures. The antioxidant may be used singly, or two or more thereof may be used in any combination and ratio.

Examples of the antioxidant include: hindered phenol-based antioxidants, hindered amine-based antioxidants, phosphorus-based antioxidants, and sulfur-based antioxidants. From the viewpoint of light resistance, a hindered phenol-based antioxidant is preferred. Specific examples of the antioxidant include: Irganox 1010, Irganox 1010FF, Irganox 1035, Irganox 1035FF, Irganox 1076, Irganox 1076FD, Irganox 1098, Irganox 1135, Irganox 1330, Irganox 1726, Irganox 1425WL, Irganox 1520L, Irganox 245, Irganox 245FF, Irganox 259, Irganox 3114, Irganox 565, and Irganox 565DD (all are trade names; produced by BASF Japan Ltd.); and ADK STAB AO-20, ADK STAB AO-30, ADK STAB AO-50, ADK STAB AO-60, and ADK STAB AO-80 (all are trade names; produced by ADEKA Corporation). Among these, the preferred antioxidants are Irganox 1010 and ADK STAB AO-60.

When the photosensitive composition according to the present embodiment contains an antioxidant, the content of the antioxidant is preferably 0.1 mass % or more and 5 mass % or less with respect to the total amount of the photosensitive composition.

1-4-5. Molecular Weight Modifier

The photosensitive composition according to the present embodiment preferably contains a molecular weight modifier from the viewpoint of suppressing increase in the molecular weight of the polymer produced by polymerization and exhibiting excellent storage stability. The molecular weight modifier may be used singly, or two or more thereof may be used in any combination and ratio.

Examples of the molecular weight modifier include: mercaptans (excluding those corresponding to polythiol (B)), xanthogens, quinones, and hydroquinones. Specific examples of the molecular weight modifier include: 1,4-naphthoquinone, 1,2-benzoquinone, 1,4-benzoquinone, methyl-p-benzoquinone, anthraquinone, hydroquinone, methylhydroquinone, tert-butylhydroquinone, 2,5-di-tert-butylhydroquinone, 2,5-di-tert-amylhydroquinone, 1,4-dihydroxynaphthalene, 3,6-dihydroxybenzonolbornane, 4-methoxyphenol, 2,2′,6,6′-tetra-tert-butyl-4,4′-dihydroxybiphenyl, 3-(3,5-di-tert-butyl-4-hydroxyphenyl)stearylpropionate, 2,2′-methylenebis(6-tert-butyl-4-ethyl phenol), 2,4,6-tris(3′,5′-di-tert-butyl-4′-hydroxybenzyl)mesitylene, pentaerythritol tetrakis[3-(3,5-di-tert-butyl-4-hydroxyphenyl)propionate], 4-tert-butylpyrocatechol, N-hexylmercaptan, N-octylmercaptan, N-dodecylmercaptan, tert-dodecylmercaptan, thioglycolic acid, dimethyl xanthogen sulfide, diisopropyl xanthogen disulfide, 2,6-di-tert-butyl-p-cresol, 4,4′-butylidenebis(6-tert-butyl-m-cresol), 4,4′-thiobis(6-tert-butyl-m-cresol), 2,4-diphenyl-4-methyl-1-pentene, phenothiazine, and 2-hydroxy-1,4-naphthoquinone. Among these, the molecular weight modifier is preferably a naphthoquinone-based molecular weight modifier, more preferably 2-hydroxy-1,4-naphthoquinone, from the viewpoint of exhibiting excellent storage stability.

1-4-6. Ultraviolet Absorber

The photosensitive composition according to the present embodiment preferably contains an ultraviolet absorber from the viewpoint of suppressing decrease in the transparency of the cured film formed by curing. The ultraviolet absorber may be used singly, or two or more thereof may be used in any combination and ratio.

Specific examples of the ultraviolet absorber include: TINUVIN P, TINUVIN 120, TINUVIN 144, TINUVIN 213, TINUVIN 234, TINUVIN 326, TINUVIN 571, and TINUVIN 765 (all are trade names; produced by BASF Japan Ltd.).

When the photosensitive composition according to the present embodiment contains an ultraviolet absorber, the content of the ultraviolet absorber is preferably 0.01 mass % or more and 10 mass % or less with respect to the total amount of the photosensitive composition.

1-4-7. Anti-Aggregation Agent

When the photosensitive composition according to the present embodiment contains the organic solvent (C), from the viewpoint of blending (i.e., compatibilizing) the double-decker silsesquioxane (A), the polythiol (B), other components contained as necessary, and the organic solvent (C) and preventing aggregation, the composition preferably contains an anti-aggregation agent. The anti-aggregation agent may be used singly, or two or more thereof may be used in any combination and ratio.

Specific examples of the anti-aggregation agents include: DISPERBYK-145, DISPERBYK-161, DISPERBYK-162, DISPERB YK-163, DISPERBYK-164, DISPERB YK-182, DISPERB YK-184, DISPERB YK-185, DISPERBYK-2163, DISPERBYK-2164, BYK-2205, DISPERBYK-191, DISPERBYK-199, and DISPERBYK-2015 (all are trade names; produced by BYK-Chemie Japan K.K.); FTX-218, FTERGENT 710FM, and FTERGENT 710FS (all are trade names; produced by NEOS Co., Ltd.); and FLOWLEN G-600 and FLOWLEN G-700 (all are trade names; produced by Kyoeisha Chemical Co., Ltd.).

When the photosensitive composition according to the present embodiment contains an anti-aggregation agent, the content of the anti-aggregation agent is preferably 0.01 mass % or more and 10 mass % or less with respect to the total amount of the photosensitive composition.

1-5. Storage of Photosensitive Composition

The photosensitive composition according to the present embodiment is preferably stored in a temperature range of −30° C. or higher and 25° C. or lower because the composition has good stability over time. A storage temperature of −20° C. or higher and 10° C. or lower is more preferred because no precipitate is generated.

### 2. Cured Film Obtained from Photosensitive Composition

The photosensitive composition according to the present embodiment can be obtained by mixing the double-decker silsesquioxane (A) having two or more polymerizable double bonds, the polythiol (B), and, if necessary, the organic solvent (C) and other components.

When the photosensitive composition prepared as described above is in the form of a solution, the photosensitive composition can be used as it is as a varnish for making a cured film, and when the photosensitive composition is not in the form of a solution, the organic solvent (C) is further added to the prepared photosensitive composition to form a solution, which is used as a varnish for making a cured film. The base material surface is coated with this varnish after this varnish is irradiated with light, or, the coating film obtained by coating the base material surface with this varnish is irradiated with light. After this, for example, by drying the varnish by heating or the like, a cured film of the photosensitive composition can be formed. Examples of the light with which the varnish is irradiated include ultraviolet rays. Irradiation of the varnish with ultraviolet light can be performed by a known device such as a spot UV irradiation device. Coating of the base material surface with the varnish can be performed by conventionally known methods such as drop casting, spin coating, roll coating, dipping, and slit coating. Next, the obtained coating film is pre-fired on a hot plate, an oven, or the like. The pre-firing conditions vary depending on the type and blending ratio of each component, but are usually at a temperature of 70° C. or higher and 150° C. or lower for 5 to 15 minutes in an oven or 1 to 5 minutes in a hot plate. After that, main firing is performed to cure the coating film. The main firing conditions vary depending on the type and blending ratio of each component, but by performing heat treatment usually at a temperature of 80° C. or higher and 130° C. or lower, preferably 90° C. or higher and 110° C. or lower, for 30 to 90 minutes in an oven or 5 to 30 minutes in a hot plate, a cured film can be obtained.

The cured film obtained in this manner has not only excellent heat resistance but also self-repairing properties. Moreover, in a preferred aspect of the present embodiment, the cured film also has high transparency. Therefore, the cured film obtained from the photosensitive composition according to the present embodiment can be suitably used, for example, as a protective film for LED emitters.

### Examples

Next, the disclosure will be described in details with reference to Examples and Comparative Examples, but the disclosure is not limited to these Examples.

The compounds used in Examples and Comparative Examples are described below.

### Component (A): Double-decker silsesquioxane

XQ1089 (trade name): produced by JNC Corporation, a compound represented by formula (Ia).

### Component (B): Polythiol

EGMP-4 (trade name): tetraethylene glycol bis(3-mercaptopropionate) produced by SC Organic Chemical Co., Ltd.
TMMP (trade name): produced by SC Organic Chemical Co., Ltd., a ternary mixture containing (1) 2-ethyl-2-{[(3-sulfanylpropanoyl)oxy]methyl}propane-1,3-diyl bis(2-ethyl)-2-{[(3-sulfanylpropanoyl)oxy]methyl}propane-1,3-diyl=bis(3-sulfanylpropanoate) (main component), (2) 2-ethyl-2-[({3-[(3-sulfanylpropanoyl)sulfanyl]propanoyl}oxy)methyl]propane-1,3-diyl bis(3-sulfanylpropanoate), and (3) 2-ethyl-2-(hydroxymethyl)propane-1,3-diyl bis(3-sulfanylpropanoate).
Multhiol Y-4 (trade name): produced by SC Organic Chemical Co., Ltd., wherein 3-{3-(3-mercaptopropoxy)-2,2-bis[(3-mercaptopropoxy)methyl]propoxy}-1-propanethiol is a main component, the main component is an alkali-treated product of a reaction product of (1) a reaction product of pentaerythritol and 3-chloro-1-propene, which contains tetrakis[(allyloxy)methyl]methane as a main component, and (2) S-thioacetic acid.

### Component (C): Organic Solvent

THF: Tetrahydrofuran (trade name) produced by FUJIFILM Wako Pure Chemical Corporation

### Other Components

TAIC (trade name): triallyl isocyanurate produced by Mitsubishi Chemical Corporation

(Preparation of Varnish)

As Examples 1 to 8 and Comparative Example 1, varnishes having the compositions shown in Table 1 were prepared. Each component was put into a glass screw tube, and stirred and dissolved to obtain a varnish.

In the table, the content of each component is the content when the total amount of varnish is 100 mass %.

(Preparation of Cured Film)

The varnish was irradiated with UV light (wavelength: 365 nm) using a spot UV irradiation device [Spot Cure SP-11 (trade name), made by Ushio Inc.] such that the integrated UV exposure amount was 140 J/cm². Various base materials are coated with this by drop casting to a thickness of 100 to 200 nm and dried on a hot plate at 100° C. for 15 minutes to obtain a cured film. Table 1 shows the thickness of the obtained cured film. Here, in the film-formation aspect, x was given to those that did not cure and remained in a liquid state.

(Evaluation of Self-Repairing Properties)

The obtained cured film was scratched with a spatula and visually observed one day later. A case the scratch disappeared was rated as o, and a case where the scratch remained was rated as x.

(Evaluation of heat resistance)

The heat resistance of the obtained cured film was evaluated by the thermal weight loss amount by TG-DTA. The temperature was raised from 30° C. to 550° C. at a rate of 10° C./min, and the measurement was performed. Using the weight loss amount at 100° C. as a reference value, the weight loss amount at 300° C. was determined. A case where the weight loss amount at 300° C. was less than 10% was evaluated as o, and a case where the weight loss amount was 10% or more was evaluated as x.

(Evaluation of Transparency)

The transparency of the obtained cured film was evaluated by UV-VIS transmittance. A case where the transmittance at a wavelength of 400 nm was 90% or more was evaluated as o, and a case where the transmittance was less than 90% was evaluated as x.

TABLE 1

| | | | Example | Example | Example | Example | Example | Example | Example | Example | Comparative |
|---|---|---|---|---|---|---|---|---|---|---|---|
| | | | 1 | 2 | 3 | 4 | 5 | 6 | 7 | 8 | Example 1 |
| Double-decker | XQ1089 | Molar | 1.0 | 1.0 | 0.9 | 1.0 | 0.7 | 1.0 | 1.0 | 1.0 | — |
| silsesquioxane | | ratio | | | | | | | | | |
| (A) | | wt % | 11.5 | 11.4 | 11.3 | 11.4 | 1.09 | 11.3 | 11.0 | 13.8 | — |
| Polythiol (B) | EGMP-4 | Molar | 1.0 | 0.9 | 1.0 | 0.7 | 1.0 | — | — | — | 0.9 |
| | | ratio | | | | | | | | | |
| | | wt % | 3.5 | 3.2 | 3.5 | 2.5 | 3.4 | — | — | — | 3.2 |
| | TMMP | Molar | — | 0.1 | — | 0.3 | — | 1.0 | — | — | 0.1 |
| | | ratio | | | | | | | | | |
| | | wt % | — | 0.4 | — | 1.1 | — | 3.7 | — | — | 0.4 |
| | Multhiol | Molar | — | — | — | — | — | — | 1.0 | 0.25 | — |
| | Y-4 | ratio | | | | | | | | | |
| | | wt % | — | — | — | — | — | — | 4.0 | 1.2 | — |
| Organic | THF | Solid | 15 | 15 | 15 | 15 | 15 | 15 | 15 | 15 | 15 |
| solvent (C) | | content | | | | | | | | | |
| | | conc. | | | | | | | | | |
| | | wt % | 85 | 85 | 85 | 85 | 85 | 85 | 85 | 85 | 85 |
| Other | TAIC | Molar | — | — | 0.1 | — | 0.3 | — | — | — | 1.0 |
| compounds | | ratio | | | | | | | | | |
| having | | wt % | — | — | 0.2 | — | 0.7 | — | — | — | 11.4 |
| polymerizable | | | | | | | | | | | |
| double bond | | | | | | | | | | | |

| | | | | | | | | | | |
|---|---|---|---|---|---|---|---|---|---|---|
| Characteristics | Film formation | ∘ | ∘ | ∘ | ∘ | ∘ | ∘ | ∘ | ∘ | x |
| | Film thickness | 150 | 150 | 150 | 150 | 150 | 150 | 150 | 150 | 150 |
| | [nm] | | | | | | | | | |
| | Self-repairing | ∘ | ∘ | ∘ | ∘ | ∘ | ∘ | ∘ | ∘ | — |
| | properties | | | | | | | | | |
| | Heat resistance | ∘ | ∘ | ∘ | ∘ | ∘ | ∘ | ∘ | ∘ | x |
| | Weight loss at | 6 | 6 | 6 | 7 | 5 | 7 | 6 | 6 | 56 |
| | 300° C. | | | | | | | | | |
| | Transparency | ∘ | ∘ | ∘ | ∘ | ∘ | ∘ | ∘ | ∘ | — |
| | Transmittance at | >90 | >90 | >90 | >90 | >90 | >90 | >90 | >90 | — |
| | 400 nm [T %] | | | | | | | | | |

It is clear from the results shown in Table 1 that the photosensitive compositions of Examples 1 to 8 gave cured films by light irradiation and low-temperature heating of 150° C. or less, and the obtained cured films had high heat resistance and self-repairing properties. On the other hand, it can be seen that Comparative Example 1 did not satisfy one or more of these characteristics.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A photosensitive composition, comprising:
a double-decker silsesquioxane (A) having two or more polymerizable double bonds; and
a polythiol (B).

2. The photosensitive composition of claim 1, wherein
the double-decker silsesquioxane (A) having two or more polymerizable double bonds is a silsesquioxane represented by formula (1) below, 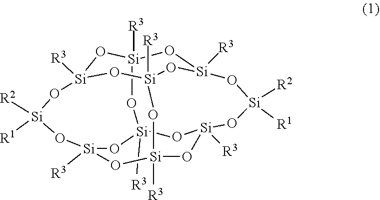
wherein in formula (1), R¹ is a substituted or unsubstituted hydrocarbon group of 2 to 20 carbons having a polymerizable double bond, or a group represented by R⁴(R⁵)₂SiO—, R⁴ is a substituted or unsubstituted hydrocarbon group of 2 to 20 carbons having a polymerizable double bond, R⁵'s are each independently a substituted or unsubstituted hydrocarbon group of 1 to 20 carbons, R²'s and R³'s are each independently a substituted or unsubstituted hydrocarbon group of 1 to 20 carbons, a plurality of R¹'s may be the same as or different from each other, a plurality of R²'s may be the same as or different from each other, a plurality of R³'s may be the same as or different from each other, when there is a plurality of R⁴'s, the plurality of R⁴'s may be the same as or different from each other, and when there is a plurality of R⁵'s, the plurality of R⁵'s may be the same as or different from each other.

3. The photosensitive composition of claim 1, wherein
the double-decker silsesquioxane (A) having two or more polymerizable double bonds is a silsesquioxane represented by formula (Ia),

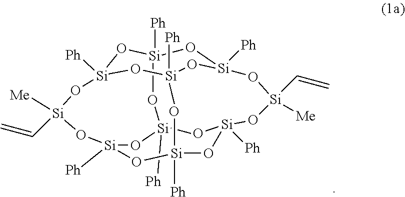 [SMILES: C=C[Si]1(C)O[Si]2(c3ccccc3)O[Si]3(c4ccccc4)O[Si]4(c5ccccc5)O[Si](C)(C=C)O[Si]5(c6ccccc6)O[Si](c6ccccc6)(O[Si](c6ccccc6)(O1)O[Si](c1ccccc1)(O5)O[Si](c1ccccc1)(O2)O4)O3]

4. The photosensitive composition of claim 1, wherein
a content of the polythiol (B) is 5 parts by mass or more and 40 parts by mass or less with respect to 100 parts by mass of the double-decker silsesquioxane (A).

5. The photosensitive composition of claim 1, further comprising:
an organic solvent (C).

6. A cured film obtained by curing the photosensitive composition of claim 1.

7. A cured film obtained by curing the photosensitive composition of claim 2.

8. A cured film obtained by curing the photosensitive composition of claim 3.

9. A cured film obtained by curing the photosensitive composition of claim 4.

10. A cured film obtained by curing the photosensitive composition of claim 5.
